(19) United States
(12) Patent Application Publication
(10) Pub. No.: US 2015/0225839 A1
(43) Pub. Date: Aug. 13, 2015

(54) SPUTTER COATING A WORK PIECE

(71) Applicant: Winona PVD Coatings, LLC, Warsaw, IN (US)

(72) Inventors: Jamie Visker, Palm Beach Gardens, FL (US); Scott L. Eyink, Hinckley, OH (US); Raymond Walker, Elkhart, IN (US)

(21) Appl. No.: 14/180,047

(22) Filed: Feb. 13, 2014

(51) Int. Cl. C23C 14/16; C23C 14/46; C23C 14/34; C23C 14/20; C23C 14/35

(52) U.S. Cl. CPC C23C 14/16; C23C 14/20; C23C 14/35; C23C 14/352; C23C 14/34; C23C 14/3464; C23C 14/46

(57) ABSTRACT

A method and a component are disclosed with a solid work piece being an outdoor-environment exposed vehicular component selected from the group consisting of: a wheel, a body panel, and exterior trim, and sputter depositing at least one metal alloy coating on at least a portion of the work piece. A metal alloy coating is sputtered on with aluminum, chromium and nickel.

### BACKGROUND

The present invention relates to sputter coating, and more specifically to sputter coating with selected metal alloys.

Sputter coating of a variety of items, such as sports trophies, vehicle wheels, semiconductors, metal parts, and otherwise have been undertaken. Chromium on aluminum layer is known. For example, U.S. Pat. No. 7,132,130 B1 to Kloss provides a sputter coating with either: a first layer of aluminum, followed by a layer of chromium, followed by another layer of aluminum; or, which consists of aluminum and chromium being simultaneously co-deposited. This was said to have been different from “vapor deposition of a nickel/chromium layer” of U.S. Pat. No. 6,399,152 B1 to Goodrich (“applied layer comprising approximately 50-80% Nickel and 50-20% Chromium . . . applying a Chromium metallic layer via a sputtering process over said Nickel/Chromium layer, said applied Chromium layer comprising approximately 99.99% Chromium”). U.S. Pat. No. 4,131,530 to Blum shows sputtering a target consisting essentially of 5 to 30% iron with scavenger elements and chromium. U.S. Pat. No. 5,656,335 to Schwing et. al. describes burned on lacquer base with a “metal such as aluminum, chromium, titanium, silver or gold . . . vaporized in the plasma . . . ”. U.S. Pat. No. 4,931,366 to Mullaney, Jr. shows a transparent base coat and a transparent top coat with metal therebetween, with sputter coating of Type 304 stainless steel or brass alloy (60/40) in the examples. It also states, “Elemental metals may be utilized to present the appearance customarily associated therewith, such as aluminum, silver, gold, copper, chromium, nickel, and alloys thereof. When sputter coating is employed, metal alloys may be deposited to present the metallic appearance customarily associated with those alloys, i.e., brass and stainless steel. Thus, the process enables a wide choice of metallic finishes. Although the initial metallic deposit and the decorative metallic layer will normally utilize the same metal (or alloy), it is possible that two different metals could be employed for special properties, or for special appearance effects by masking during the two steps.” Moreover, U.S. Pat. No. 4,247,600 to Adachi shows a layer of chromium deposited over a layer of copper.

### SUMMARY

The present invention is set forth by the patent claims and only those. To summarize, without limitation, a method may comprise the acts of: providing a solid work piece being an outdoor-environment exposed vehicular component selected from the group consisting of: a wheel, a body panel, and exterior trim, and sputter depositing at least one metal alloy coating on at least a portion of the work piece. A metal alloy coating is sputtered on with aluminum, chromium and nickel.

A component, such as an outdoor-environment exposed vehicular component selected from the group consisting of: a wheel, a body panel, and exterior trim, is provided with a metal alloy coating sputtered on with aluminum, chromium and nickel.

These and other objects and features are set forth further below.

### BRIEF DESCRIPTION OF THE DRAWINGS

FIG. 1 is a schematic view of one method of coating.

FIG. 2 is a partial cross-sectional view of one example of a coated work piece.

FIG. 3 is a partial cross-sectional view of another example of a coated work piece.

FIG. 4 is a partial cross-sectional view of another example of a coated work piece.

FIG. 5 is a partial cross-sectional view of another example of a coated work piece.

### DESCRIPTION OF THE SELECTED EMBODIMENTS

For the purpose of promoting an understanding of the principles of the invention, reference will now be made to the embodiments illustrated in the drawings and specific language will be used to describe the same. It will nevertheless be understood that no limitation of the scope of the invention is thereby intended. Any alterations and further modifications in the described embodiments, and any further applications of the principles of the invention as described herein are contemplated as would normally occur to one skilled in the art to which the invention relates. One embodiment of the invention is shown in great detail, although it will be apparent to those skilled in the relevant art that some features that are not relevant to the present invention may not be shown for the sake of clarity.

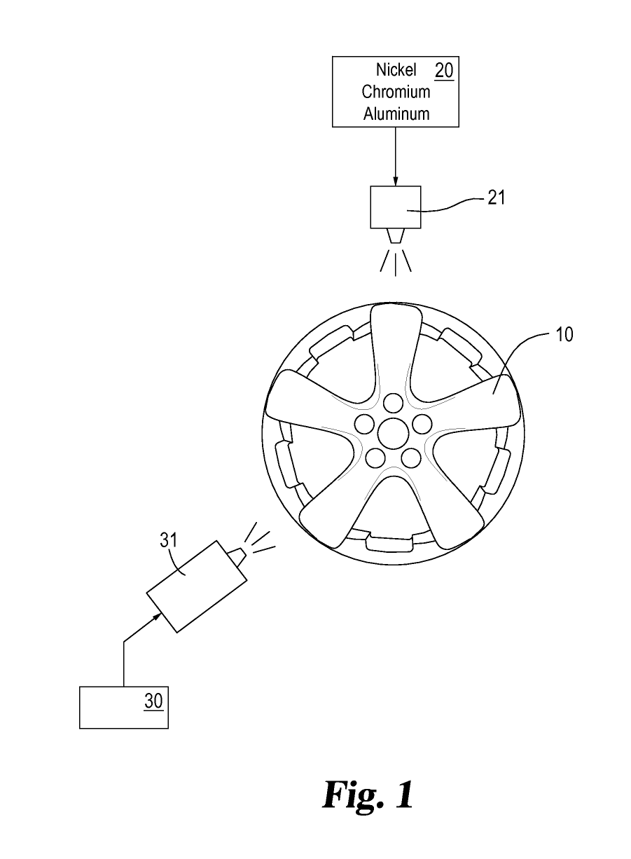

Referring to the examples shown in the drawings (FIGS. 1-5), a method for coating a surface is shown and a coated work piece 10. The method may comprise the acts of: providing a solid work piece 10, the work piece being an outdoor-environment exposed vehicular component selected from the group consisting of: a wheel 10, a body panel, and exterior trim, and sputter depositing at least one metal alloy coating 120 and/or 220 on at least a portion of the work piece.

Optionally, the work piece may be from any variety of items and/or fields, including without limitation, tools, automotive and/or other vehicle parts, (e.g. lamps and lamp reflectors, interior trim, outdoor-environment exposed vehicular component such as a wheel, a body panel, exterior trim, etc.), orthopedics (e.g. implants, instruments and/or cases or trays), other medical devices and implants, vehicle siding, mirrors, housings (e.g. the housing for a drill, alarm clock, phone, luggage, or otherwise), shielding, satellites and space-craft, pottery and dishes, boats and ships, utensils, or any other variety of manufactured items.

Of those, optionally but not necessarily the work piece may have a high coefficient of linear thermal expansion and/or may be used in environments of significant temperature changes. For example, Table 1 below shows a few examples of optional materials of which all or a part thereof (core or otherwise) may be made:

TABLE 1
Example linear coefficients of thermal expansion at 20° C.
In micron per meter per degree Kelvin (K)

| | |
|---|---|
| Titanium | 8.6 |
| Platinum | 9 |
| Carbon steel | 10.8 |
| Steel | 11.0~13.0 |
| Iron | 11.8 |
| Concrete | 12 |
| Nickel | 13.4 |
| Gold | 14 |
| Copper | 16.5 |
| Stainless steel | 17.3 |
| Silver | 18 |
| Brass | 19 |
| Aluminum | 23.1 |
| Magnesium | 26 |
| Douglas-fir | 27-45 |
| Lead | 29 |
| Zinc | 30.2 |
| ABS plastic (glass fiber | 30.4 |
| reinforced) | |
| PVC | 52 |
| Oak (perpendicular) | 54 |
| ABS plastic | 73.8 |

Optionally but not necessarily the solid work piece 10 has a linear coefficient of thermal expansion at 20° C. greater than 10. Optionally but not necessarily the solid work piece has a linear coefficient of thermal expansion at 20° C. greater than 15 and less than 40.

The metal alloy coating 120 and/or 220 comprises, (and optionally consists of, or consists essentially of) aluminum, chromium and nickel, as follows. The weight percent of these may vary, but include about 50 to 80 weight percent aluminum, about 5 to 25 weight percent chromium; and, about 5 to 25 weight percent nickel. However, optionally but more preferably the weight percentages of nickel and chromium are each about 10 to 25 weight percent. And at least one example may optionally be about 60 weight percent aluminum, about 20 weight percent to chromium; and about 20 weight percent nickel. Such aluminum may be replace with an aluminum alloy, with aluminum and one or more metals other than the chromium and nickel already accounted for in these ranges. The sputtered metal alloy coating preferably includes sufficient chromium to provide a mirror finish; and, nickel in an amount less than 50 weight percent nickel; and, aluminum in an amount at least 50 weight percent of aluminum, wherein the metal alloy coating forms a mirror finish. Some other non-limiting examples within the claimed ranges are set forth in the prophetic examples below. Optionally but not necessarily metal alloy coating is free of silicates. Trace impurities and/or other ingredients less that 1% by weight percent are permitted in these ranges except where, if at all, expressly stated otherwise.

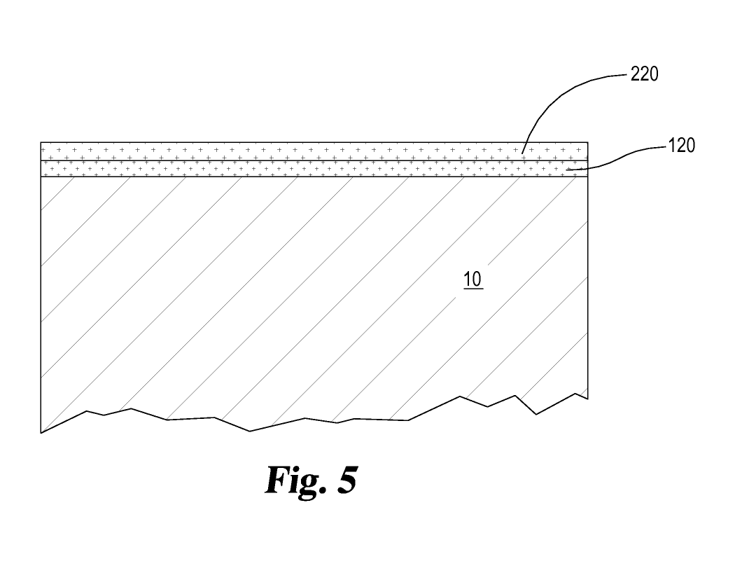

The method optionally but not necessarily may include the feature where the sputtering is from a single target or source 20 (FIG. 1), the target comprising combination of the metals (pressed powder or otherwise). Optionally but not necessarily the aluminum, chromium and nickel metals are deposited from a single target consisting essentially of aluminum, chromium and nickel. Typically, sputtering is from one or more gun or applicator 21. Or, it may be that optionally the sputtering is from more than one (e.g. two or three or more) targets made from the same or from different metals and/or different alloys. This may be done with concurrent (which includes partially concurrent, i.e. partially overlapping in time) and/or non-concurrent sputtering from various targets. Moreover, optionally but not necessarily sputtering from one or more of the targets may be done with the energy level for sputtering being constant, increased, decreased and/or modulated as a function of time, for one or more target. As such, for just one example, if target A has a higher weight percent of nickel than target B, the energy level and the associated material from target A deposited therefrom may be increased during the end of the sputtering. This may result in a region (or sub-layer) of the metal coating nearer the surface with a proportionally higher percentage of nickel near the surface, such as to enhance acid resistance. This may be done in series as yet another option. FIG. 5 diagrams work piece 10 with a first metal alloy coating or region 120 and a second metal alloy coating or region 220 thereon. They optionally, when used, may be discrete or blended.

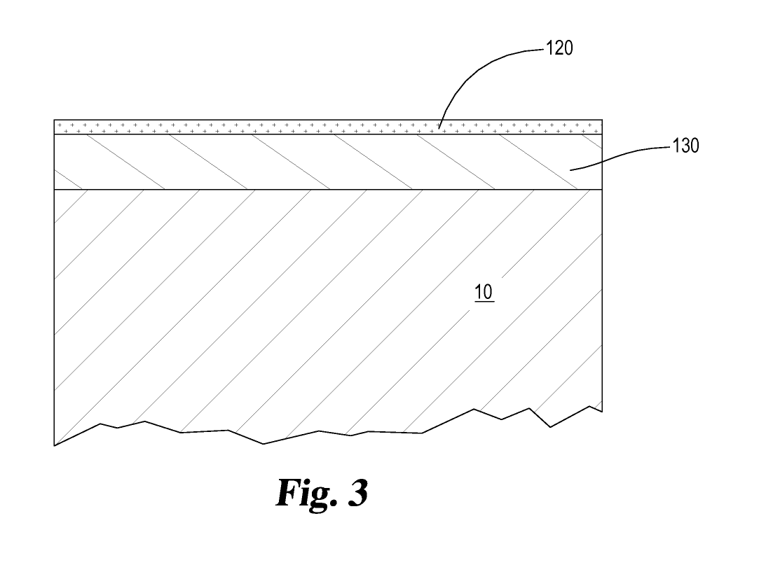

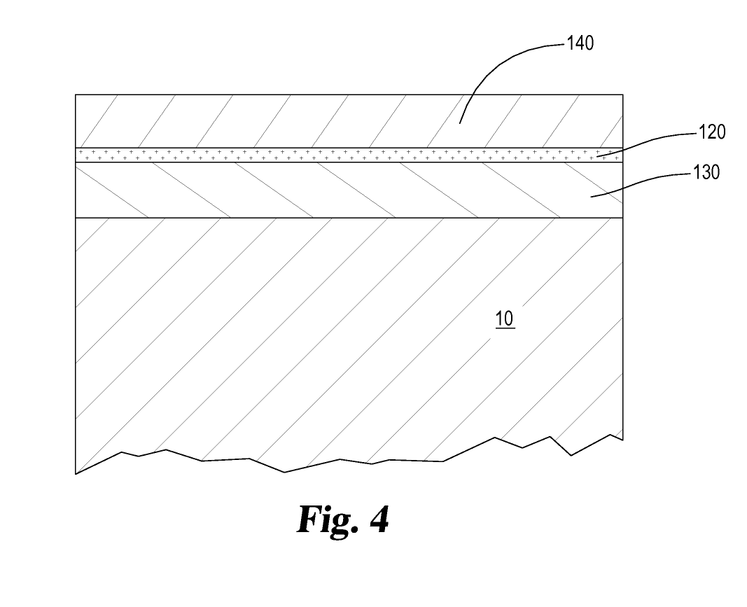

The method optionally but not necessarily may include the feature where the work piece 10 comprises a metal core having a heat-melted polymer powder coating 130 (see for example FIG. 3 and FIG. 4) thereon. The method optionally but not necessarily may include the feature where the work piece comprises an aluminum vehicle wheel 10. For example, one or more such polymer coatings may be from a source 30 of the polymer coating(s) with an applicator 31 (spray gun, electrostatic applicator, or otherwise)(FIG. 1). Heat may be used to melt such coatings, which may be for example thermoset and/or thermoplastic. Base coatings are normally done after cleaning the metal core of the work piece and before sputtering. Top coating, such as 140, is typically done afterwards, when done.

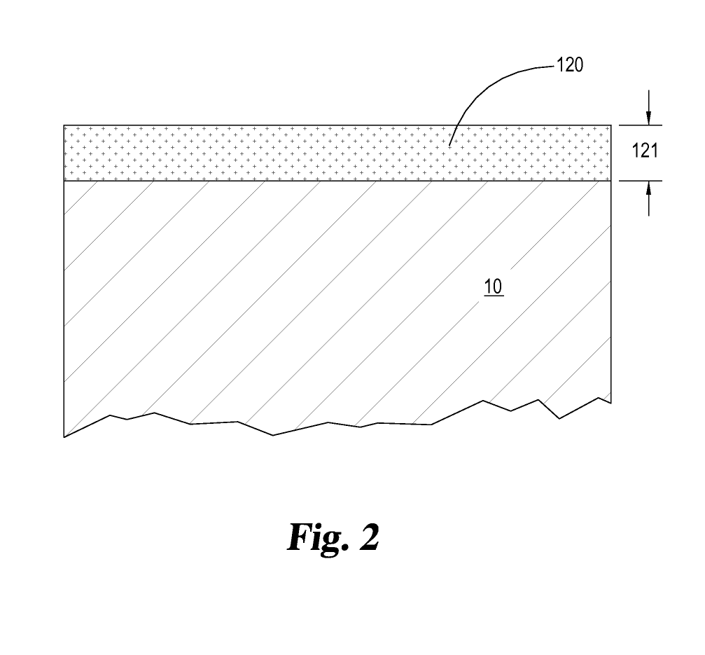

Optionally but not necessarily the coating has an average thickness (for example 121, FIG. 2) greater than 300 angstroms and less than 2,000 angstroms. It may, however, be more or less.

Optionally, the metal alloy coating may an average thickness greater than 300 angstroms and less than 700 angstroms, and may be about 500 angstroms thick, and is light transmissive. The thinner layers may be used to provide coloration from the work piece and/or from layer 130.

In another option, the metal alloy coating has an average thickness of at least about 1,000 angstroms, and may be about 1,200 angstroms, and is not light transmissive.

Optionally but not necessarily the metal coating may have a tensile strength that, for a to given thickness, the coating withstands an ultimate tensile stress up to about 300, and preferably up to about 400 mega-pascals (MPa). However, in some applications greater or lesser such stress values may be suitable.

Optionally but not necessarily the work piece comprises a metal portion having a polymer powder coating 130 (FIGS. 3 and 4) and/or 140 (FIG. 4) thereon. Optionally but not necessarily the metal alloy coating forms a mirror finish. When such is the case or not, optional polymer coating 140 may preferable be clear, as for example a clear coat for protection. Layers 130 and/or 140 may each comprise a single layer or multiple sub-layers. Layers 130 and/or 140 (as well as other layers) may each be included or not in any of the examples described or drawn (FIGS. 1, 2, 5).

Optionally but not necessarily the alloy coated work piece may be used in rugged and/or corrosive environments and may need to be durable therein. And, optionally but not necessarily the alloy coated work piece may pass one or more of the following tests: (a) adhesion of coating, ASTM D-3359-02; (b) Stone chip resistance, SAE J400 0.5 L (1.05 pts.) of gravel at 23 deg. C (74 deg. F) and −20 deg. C; (c) acid test, chemical resistance to acidic Eagle One (brand) Chrome & Wheel Cleaner, 665856 (Ashland) (the formula for which, per MSDS R0336584, Version 3.8 (Aug. 22, 2012), includes, among other things: phosphoric acid about 5-10% concentration: ethanedioic acid, diydrate about 1.5-5% concentration; sulfuric acid about 0.5-1% concentration; and, hydrofluoric acid about 0.1-0.9% concentration) listed therein with a pH of 2.8 (in house test method based on SAE J2792); and/or (d) Thermal Shock Test for Coating Adhesion, Ford Laboratory Test Method BI 107-05.

As used here (claims, specification, and other definitions) the following terms have the following meaning:

Articles and phases such as, “the”, “a”, “an”, “at least one”, and “a first”, “comprising”, “having” and “including” here are not limited to mean only one, but rather are inclusive and open ended to also include, optionally, two or more of such elements and/or other elements. In terms of the meaning of words or terms or phrases herein, literal differences therein are not superfluous and have different meaning, and are not to be synonymous with words or terms or phrases in the same or other claims.

The phrase “consisting essentially of” means specified materials and/or ingredient and/or steps and/or acts and/or other elements, and to those that do not materially affect the invention's basic and novel characteristics in the claim (as a transition) or the element or the group.

The phrase “consisting of” means to only include exactly what is stated, and excludes any step, act, material ingredient, or element not specified in the claim (as a transition) or the element or the group, but does not necessarily require the absence of trace amounts (less than 1% by weight) of impurities.

The term “and/or” is inclusive here, meaning “and” as well as “or”. For example, “P and/or Q” encompasses, P, Q, and P with Q; and, such “P and/or Q” may include other elements as well.

The term “means” and/or “means for” and/or “step” and/or “step for” here, if and when used in a claim, invokes 35 U.S.C. §112(f) means-plus-function for the recited function(s) and the corresponding structure(s) or act(s)(including alternatives in the definitions or elsewhere in this disclosure) and equivalents thereto.

The term “coating” as used herein has the meaning, one or more layers on or over some other structure or layer. A coating may have one or more layers or regions intermediate of it and that which it coats.

The term “light transmissive” as used herein has the meaning that a coating or layer allows at least about 20 percent of the intensity of visible white light to pass through it in one direction, whether or not partially refracted or scattered.

The term “solid work piece” as used herein has the meaning, an article (one piece or multi-piece) that is not liquid or gas. It may be made of any one or more material (including without limitation those listed in Table 1), and may be with or without one or more coatings, heat-melted powder coating(s) or otherwise.

The term “metal alloy” as used herein has the meaning, a homogeneous mixture or solid solution of two or more metals, the atoms of one replacing or occupying interstitial positions between the atoms of the other(s).

The term “outdoor-environment exposed vehicular component” part of a vehicle (car, truck, motorcycle, boat, plane, etc.) that in its normal location is on the outside of the vehicle such that it is subject to exposure to one or more of rain, hail, road salt, rocks and/or road grime.

The term “alloy metals” as used herein has the meaning two or more metals that are, or will be, alloyed to each other to form a metal alloy.

The term “average thickness” as used herein has the meaning the average thickness for a given area by taking five thickness samples randomly over any one 1-centimeter diameter circular area therein, or for smaller area surfaces five such samples randomly over such entire smaller surface.

The term “silicates” as used herein has the meaning a compound containing an anionic silicon compound.

The term “weight percent” as used herein has the meaning the percentage by weight of a particular component (such as a metal) of what it is a part of, typically here a an alloy, coating, a coating layer and/or a target,

The term “sputter depositing” as used herein has the meaning, of depositing or deposition of a thin film by sputtering, a process whereby atoms are ejected from a solid target material due to bombardment of the target by energetic particles. It may include, without limitation, plasma vapor deposition, physical vapor deposition, electronic sputtering, potential sputtering, magnetron sputtering, pulsed laser deposition, ion beam sputtering, ion assisted deposition, gas flow sputtering, and otherwise.

The term “target” as used herein has the meaning a source of material, typically metal and/or metal and/or metal alloy and/or metal or alloy mixture (powder, including without limitation made from metal powders by a hot isostatic pressing (HIP) process, or otherwise), used in sputter deposition.

The term “metal core” as used herein has the meaning, a part of a work piece that is both metal and located beneath a non-metal coating.

The term “polymer coating” as used herein has the meaning, of a coating formed by applying a polymer powder to one or more surface (by spraying, dipping, electro-static application or otherwise) and melting it on such surface such that the it melts or fuses together to form a coating. The coating may thereafter be thermo-set or thermoplastic.

By way of non-limiting example only, various testing of example Al—Cr—Ni metal alloy sputter coating (weight percents: Al: 60%, Cr: 20%, Ni: 20%) were favorable.

Other prophetic examples, falling within various claims are possible, including for example alloys with weight percents at or about: (a) aluminum 50, chromium 25, nickel 25; (b) aluminum 55, chromium 20, nickel 25; (c) aluminum 60, chromium 25, nickel 15; (d) aluminum 60, chromium 15, nickel 25; (e) aluminum 70, chromium 20, nickel 10; (f) aluminum 70, chromium 10, nickel 20; (g) aluminum 70, chromium 15, nickel 15; (h) aluminum 75, chromium 15, nickel 10; (i) aluminum 75, chromium 10, nickel 15; (j) aluminum 80, chromium 10, nickel 10; (k) aluminum 80, chromium 15, nickel 5; (l) aluminum 50+, chromium 5, nickel 10; (m) aluminum 50+, chromium 10, nickel 5, to name a few. Optionally, other metals may be alloyed, such as those listed in the background hereof. Optionally, the alloy may include sufficient chromium to provide a mirror finish; and, nickel in an amount less than 50 weight percent nickel; and, aluminum in an amount at least 50 weight percent of aluminum, and, wherein the metal alloy coating forms a mirror finish.

The invention may include any one or more articles or devices made by any of the claimed methods and/or may by different methods but with a claimed composition.

The language used in the claims and the written description and in the above definitions is to only have its plain and ordinary meaning, except for terms explicitly defined above. Such plain and ordinary meaning is defined here as inclusive of all consistent dictionary definitions from the most recently published (on the filing date of this document) general purpose Webster's dictionaries and Random House dictionaries.

While the invention has been illustrated and described in detail in the drawings and foregoing description, the same is to be considered as illustrative and not restrictive in character, it being understood that only the preferred embodiment has been shown and described and that all changes, equivalents, and modifications that come within the spirit of the inventions defined by following claims are desired to be protected. All publications, patents, and patent applications cited in this specification are herein incorporated by reference as if each individual publication, patent, or patent application were specifically and individually indicated to be incorporated by reference and set forth in its entirety herein.

1. A method for coating, comprising the acts of:
providing a solid work piece, said work piece being an outdoor-environment exposed vehicular component selected from the group consisting of: a wheel, a body panel, and exterior trim;
sputter depositing at least one metal alloy coating on at least a portion of said work piece, said metal alloy coating comprising:
(a) about 50 to 80 weight percent aluminum;
(b) about 5 to 25 weight percent chromium; and,
(c) about 5 to 25 weight percent nickel.

2. The method of claim 1 wherein said metal alloy coating comprises about 10 to 25 weight percent nickel, and about 10 to 25 weight percent chromium.

3. The method of claim 1 wherein said metal alloy coating comprises:
(a) about 60 weight percent aluminum;
(b) about 20 weight percent chromium; and,
(c) about 20 weight percent nickel.

4. The method of claim 1 wherein said metal alloy coating consists essentially of aluminum, chromium and nickel.

5. The method of claim 1 wherein said metal alloy coating consists of aluminum, chromium and nickel.

6. The method of claim 1 wherein said aluminum, chromium and nickel metals are deposited from a single target consisting essentially of aluminum, chromium and nickel.

7. The method of claim 1 wherein said solid work piece has a linear coefficient of thermal expansion at 20° C. greater than 10, and wherein said metal alloy coating has a tensile strength such that it can withstand an ultimate tensile stress up to about 400 MPa.

8. The method of claim 1 wherein said solid work piece has a linear coefficient of thermal expansion at 20° C. greater than 15 and less than 40.

9. The method of claim 1 wherein said coating has an average thickness greater than 300 angstroms and less than 2,000 angstroms.

10. The method of claim 1 wherein said work piece comprises a metal portion having a polymer powder coating thereon.

11. The method of claim 1 wherein said work piece comprises an aluminum vehicle wheel.

12. The method of claim 1 wherein said aluminum, chromium and nickel alloy metals are deposited on said work piece concurrently from one or more targets.

13. The method of claim 1 wherein said metal alloy coating forms a mirror finish.

14. The method of claim 1 wherein said metal alloy coating has an average thickness greater than 300 angstroms and less than 700 angstroms and is light transmissive.

15. The method of claim 1 wherein said metal alloy coating has an average thickness greater than 1,000 angstroms and less than 2,000 angstroms and is not light transmissive.

16. The method of claim 1 wherein said metal alloy coating is free of silicates.

17. A method for coating, comprising the acts of:
providing a solid work piece;
wherein said work piece comprises a metal wheel having polymer powder coating thereon;
sputter depositing at least one metal alloy coating concurrently on at least a portion of said work piece, said metal alloy coating comprising:
(a) sufficient chromium to provide a mirror finish; and,
(b) nickel in an amount less than 50 weight percent nickel; and,
(c) aluminum in an amount at least 50 weight percent of aluminum,
and, wherein said metal alloy coating forms a mirror finish.

18. The method of claim 17 wherein said metal alloy coating consists essentially of metals comprising:
(a) about 20 weight percent chromium;
(b) about 20 weight percent nickel; and,
(c) aluminum.

19. A coated component, comprising:
a solid work piece, said work piece being an outdoor-environment exposed vehicular component selected from the group consisting of: a wheel, a body panel, and exterior trim at least one sputter deposited metal alloy coating on at least a portion of said wheel, said metal alloy coating comprising:
(a) about 50 to 80 weight percent aluminum;
(b) about 10 to 25 weight percent chromium; and,
(c) about 10 to 25 weight percent nickel,
and, wherein said metal alloy coating forms a mirror finish.

20. The work piece of claim 19 wherein said metal alloy coating consists essentially of:
(a) about 20 weight percent chromium;
(b) about 20 weight percent nickel; and,
(c) the balance aluminum.

21. The work piece of claim 19 wherein said work piece has a polymer coating thereon.
